(19) United States
(12) Patent Application Publication
(10) Pub. No.: US 2015/0351257 A1
(43) Pub. Date: Dec. 3, 2015

(54) METHOD FOR PRODUCING WIRING BOARD

(71) Applicant: KYOCERA Circuit Solutions, Inc., Kyoto (JP)

(72) Inventors: Kohichi OHSUMI, Yasu-shi (JP); Kazuki OKA, Kusatsu-shi (JP)

(73) Assignee: KYOCERA CIRCUIT SOLUTIONS, INC., Kyoto (JP)

(21) Appl. No.: 14/722,246

(22) Filed: May 27, 2015

(30) Foreign Application Priority Data
May 28, 2014 (JP) 2014-110205
Nov. 26, 2014 (JP) 2014-239048

(51) Int. Cl. H05K 3/42; H05K 3/10; H05K 3/06; H05K 3/18

(52) U.S. Cl. CPC H05K 3/424; H05K 3/188; H05K 3/108; H05K 3/062; H05K 3/426; H05K 2203/0723; H05K 2203/072

(57) ABSTRACT

A method for producing a wiring board includes the steps of forming an upper insulating layer on a lower insulating layer having a lower wiring conductor on its upper surface; forming a via-hole in the upper insulating layer; depositing a first base metal layer in the via-hole and on an upper surface of the upper insulating layer; forming a first plating resist layer on the first base metal layer; depositing a first electrolytically plated layer to completely fill at least the via-hole; forming a via conductor, and depositing a second base metal layer; forming a second plating resist layer on the second base metal layer; depositing a second electrolytically plated layer; and forming a wiring pattern.

### BACKGROUND OF THE INVENTION

1. Technical Field

The present invention relates to a method for producing a wiring board for use in mounting a semiconductor element.

2. Background

A build-up wiring board is known as a high-density wiring board for use in mounting a semiconductor element. The build-up wiring board has a multilayer wiring structure in which wiring conductors formed above and below so as to sandwich an insulating layer between them are connected through a via conductor.

FIGS. 17A and 17B illustrate a multilayer wiring structure in a conventional build-up wiring board. FIG. 17A is an essential part cross-sectional view of the conventional build-up wiring board, and FIG. 17B is a top view thereof. Furthermore, FIG. 18 is a partially enlarged view of the essential part schematic cross-sectional view in FIG. 17A, and FIG. 19 is a partially enlarged view of the schematic top view in FIG. 17B. As illustrated in FIGS. 17A and 17B, in the conventional wiring board, a lower wiring conductor 12 is deposited on a lower insulating layer 11. An upper insulating layer 13 is deposited on the lower insulating layer 11 and the lower wiring conductor 12. Via-holes V are formed in the upper insulating layer 13. A bottom surface of the via-hole V reaches the lower wiring conductor 12. The via-hole V is filled with a via conductor 14. The via conductor 14 is connected to the lower wiring conductor 12. An upper wiring conductor 15 is deposited on the upper insulating layer 13. The upper wiring conductor 15 includes a strip-shaped pattern 15a integrally formed with the via conductor 14, and a solid pattern 15b having a large area.

Furthermore, the upper wiring conductor 15 has a land L in a portion corresponding to the via conductor 14. The land L is larger than the via-hole V and covers the via-hole V. Due to the land L, even when misalignment is generated between a formation position of the via-hole V and a formation position of the upper wiring conductor 15 due to a producing variation, the lower wiring conductor 12 and the upper wiring conductor 15 can be surely connected to each other through the via conductor 14.

However, when the land L is provided, the upper wiring conductor 15 cannot be wired with high density. Thus, Unexamined Japanese Patent Publication No. 2003-198085 discloses a circuit board capable of implementing high-density wiring by providing a wiring pattern having a width smaller than a via conductor, on the via conductor without providing the land on the via-hole, and a method for producing the same.

According to the method for producing the circuit board disclosed in the Unexamined Japanese Patent Publication No. 2003-198085, a seed layer and a plated conductor layer formed by electrolytic copper plating are formed in the via-hole and are formed on a whole upper surface of the insulating layer in which the via-hole is formed. After that, a resist pattern is formed on the plated conductor layer to cover a portion to be left as a wiring pattern, and the wiring pattern is formed by etching the plated conductor layer, with the resist pattern used as a mask. This method is called a subtractive method. Since the thick plated conductor layer formed by electrolytic copper plating layer is etched into a predetermined pattern to form the wiring pattern, large side-etching occurs in the wiring pattern under the resist pattern, so that its side surface is largely etched. Therefore, it is difficult to form a fine wiring pattern.

### SUMMARY

An object of the present invention is to provide a method for producing a wiring board capable of forming a fine wiring pattern having a width smaller than a via conductor, on the via conductor.

According to a first embodiment of the present invention, a method for producing a wiring board includes the steps of: forming an upper insulating layer on a lower insulating layer in such a manner as to cover a lower wiring conductor formed on an upper surface of the lower insulating layer; forming a via-hole in the upper insulating layer in such a manner that its bottom surface reaches the lower wiring conductor; depositing a first base metal layer in the via-hole and on an upper surface of the upper insulating layer; forming a first plating resist layer on the first base metal layer having a first opening pattern to expose the via-hole and a periphery of the via-hole; depositing a first electrolytically plated layer in the first opening pattern to completely fill at least the via-hole; forming a via conductor including the first base metal layer and the first electrolytically plated layer by removing the first plating resist layer, and recessing a surface of the first electrolytically plated layer from the surface of the upper insulating layer by 0 μm to 15 μm; depositing a second base metal layer on a surface of the via conductor and an exposed surface of the upper insulating layer; forming a second plating resist layer on the second base metal layer having a second opening pattern passing on the via-hole and having a width smaller than the via-hole; depositing a second electrolytically plated layer in the second opening pattern; and forming an upper wiring conductor including the second base metal layer and the second electrolytically plated layer by removing the second plating resist layer, and etching away the second base metal layer exposed from the second electrolytically plated layer.

According to the method for producing the wiring board in the first embodiment, after the via-hole is filled with the via conductor including the first base metal layer and the first electrolytically plated layer, the wiring pattern including the second base metal layer and the second electrolytically plated layer is formed thereon by a semi-additive method. Therefore, the via-hole can be favorably filled with the via conductor, and the wiring pattern can be finely formed.

According to a second embodiment of the present invention, as for a method for producing a wiring board including a lower insulating layer having a lower wiring conductor thereon; an upper insulating layer formed on the lower wiring conductor and the lower insulating layer; a via-hole formed in the upper insulating layer in such a manner that its bottom surface reaches the lower wiring conductor; a via conductor filled in the via-hole in such a manner that its upper end is recessed from a surface of the upper insulating layer by 0 μm to 15 μm; and an upper wiring conductor formed on the upper insulating layer and on the via conductor, and having a strip-shaped pattern passing on the via conductor and wherein the strip-shaped pattern has a width smaller than the upper end of the via conductor, the method includes the steps (1) to (7) of:

(1) forming the lower wiring conductor on the lower insulating layer;

(2) forming the upper insulating layer on the lower insulating layer and on the lower wiring conductor;

(3) forming the via-hole in the upper insulating layer;

(4) depositing a base conductor layer for electrolytic plating, on the upper insulating layer and in the via-hole;

(5) forming an electrolytically plated layer on the base conductor layer on the upper insulating layer, in the via-hole, and on a periphery of the via-hole, in a portion where the upper wiring conductor is to be formed in such a manner that the via-hole is completely filled and an area occupancy of the electrolytically plated layer in the upper surface of the upper insulating layer reaches 40% to 55%;

(6) forming the via conductor by etching a whole surface of the base conductor layer and the electrolytically plated layer in such a manner that the upper surface of the electrolytically plated layer in the via-hole is recessed from the upper surface of the upper insulating layer by 0 μm to 15 μm; and

(7) forming the upper wiring conductor on the upper insulating layer and on the via conductor by a semi-additive method.

According to the method for producing the wiring board in the second embodiment, after the via-hole formed in the upper insulating layer is filled with the via conductor whose upper end is recessed from the upper surface of the upper insulating layer by 0 μm to 15 μm, the upper wiring conductor having the strip-shaped pattern passing on the via conductor is formed by the semi-additive method, and the strip-shaped pattern has the width smaller than the upper end of the via conductor. Therefore, the fine wiring pattern can be formed on the upper insulating layer with high density.

The electrolytically plated layer is formed on the upper insulating layer in the portion where the upper wiring conductor is to be formed, and in the via-hole and its periphery, so as to completely fill the via-hole, and have the area occupancy of 40% to 55% in the upper surface of the upper insulating layer, and then the via conductor is formed by etching the whole surface of the electrolytically plated layer. Therefore, the via conductor having a small variation in thickness can be formed. This is because this area occupancy is suitable for forming the plated layer on the upper insulating layer with uniform thickness, and in this occupancy, a residue of the first electrolytically plated layer is hardly left on the upper insulating layer when the via conductor is formed by etching the electrolytically plated layer.

Furthermore, even when the residue of the electrolytically plated layer is left on the upper insulating layer, the electrolytically plated layer is formed in the portion where the upper wiring conductor is to be formed, and the upper wiring conductor is formed thereon so as to overlap it. Therefore, electric insulating reliability is not damaged in the upper wiring conductor.

### BRIEF DESCRIPTION OF THE DRAWINGS

FIG. 1 is an essential part cross-sectional view illustrating one example of a wiring board produced by a method for producing a wiring board according to a first embodiment;

FIG. 2 is an essential part top view of the wiring board illustrated in FIG. 1;

FIGS. 3A to 3L are essential part cross-sectional views each provided for describing a step in the method for producing the wiring board according to the first embodiment;

FIGS. 4A and 4B are an essential part schematic cross-sectional view and an essential part schematic top view illustrating one example of a wiring board produced by a method for producing a wiring board according to a second embodiment, respectively;

FIGS. 5A and 5B are an essential part schematic cross-sectional view and an essential part schematic top view for describing the method for producing the wiring board according to the second embodiment, respectively;

FIGS. 6A and 6B are an essential part schematic cross-sectional view and an essential part schematic top view for describing the method for producing the wiring board according to a second embodiment, respectively;

FIGS. 7A and 7B are an essential part schematic cross-sectional view and an essential part schematic top view for describing the method for producing the wiring board according to the second embodiment, respectively;

FIGS. 8A and 8B are an essential part schematic cross-sectional view and an essential part schematic top view for describing the method for producing the wiring board according to the second embodiment, respectively;

FIGS. 9A and 9B are an essential part schematic cross-sectional view and an essential part schematic top view for describing the method for producing the wiring board according to the second embodiment, respectively;

FIGS. 10A and 10B are an essential part schematic cross-sectional view and an essential part schematic top view for describing the method for producing the wiring board according to the second embodiment, respectively;

FIGS. 11A and 11B are an essential part schematic cross-sectional view and an essential part schematic top view for describing the method for producing the wiring board according to the second embodiment, respectively;

FIGS. 12A and 12B are an essential part schematic cross-sectional view and an essential part schematic top view for describing the method for producing the wiring board according to the second embodiment, respectively;

FIGS. 13A and 13B are an essential part schematic cross-sectional view and an essential part schematic top view for describing the method for producing the wiring board according to the second embodiment, respectively;

FIGS. 14A and 14B are an essential part schematic cross-sectional view and an essential part schematic top view for describing the method for producing the wiring board according to the second embodiment, respectively;

FIGS. 15A and 15B are an essential part schematic cross-sectional view and an essential part schematic top view for describing the method for producing the wiring board according to the second embodiment, respectively;

FIGS. 16A and 16B are an essential part schematic cross-sectional view and an essential part schematic top view for describing the method for producing the wiring board according to the second embodiment, respectively;

FIGS. 17A and 17B are an essential part schematic cross-sectional view and an essential part schematic top view illustrating a conventional wiring board, respectively;

FIG. 18 is a partially enlarged view of the essential part schematic cross-sectional view in FIG. 17A; and

FIG. 19 is a partially enlarged view of the schematic top view in FIG. 17B.

### DETAILED DESCRIPTION

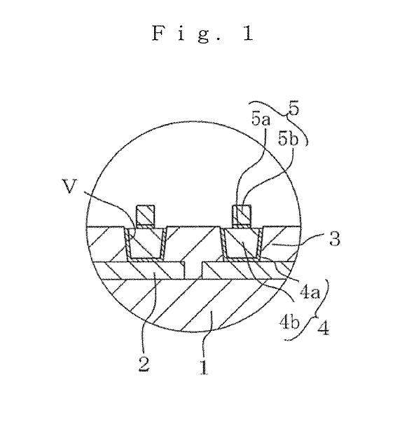

FIGS. 1 and 2 illustrate one example of a wiring board produced by a method for producing a wiring board according to a first embodiment. FIG. 1 is an essential part cross-sectional view of the wiring board, and FIG. 2 is a top view thereof. As illustrated in FIG. 1, a lower wiring conductor 2 is deposited on a lower insulating layer 1, in the wiring board. An upper insulating layer 3 is laminated on the lower insulating layer 1 and the lower wiring conductor 2. Via-holes V are formed in the upper insulating layer 3. A bottom surface of the via-hole V reaches the lower wiring conductor 2. The via-hole V is filled with a via conductor 4. The via conductor 4 is connected to the lower wiring conductor 2. An upper wiring pattern (wiring conductor) 5 is deposited on the upper insulating layer 3 and the via conductor 4.

Each of the lower insulating layer 1 and the upper insulating layer 3 is formed of an insulating material containing a thermosetting resin such as epoxy resin, bismaleimide triazine resin, allylic-modified polyphenylene ether resin, or polyimide resin. Each of the lower insulating layer 1 and the upper insulating layer 3 may contain a reinforcing sheet such as glass cloth or an insulating filler such as silica. The lower insulating layer 1 has a thickness of approximately 20 μm to 200 μm, and the upper insulating layer 3 has a thickness of approximately 20 μm to 50 μm. The lower wiring conductor 2 is a conductor layer coated with metal foil such as copper foil or plated with copper. The lower wiring conductor 2 has a thickness of approximately 5 μm to 50 μm. The via conductor 4 is formed of a first base metal layer 4a and a first electrolytically plated layer 4b. The upper wiring conductor 5 is formed of a second base metal layer 5a and a second electrolytically plated layer 5b.

As illustrated in FIG. 2, the upper wiring conductor 5 has a width smaller than the via-hole V and passes on the via-hole V. Since the width of the upper wiring conductor 5 is smaller than the via-hole V, the lower wiring conductor 2 and the upper wiring conductor 5 can be surely connected through the via conductor 4 even when misalignment is generated between a formation position of the via-hole V and a formation position of the upper wiring conductor 5 due to a producing variation. An upper end portion of the via-hole V has a diameter of approximately 40 μm to 65 μm, and a bottom portion thereof has a diameter of approximately 30 μm to 45 μm. The wiring conductor 5 has a width of approximately 30 μm to 45 μm.

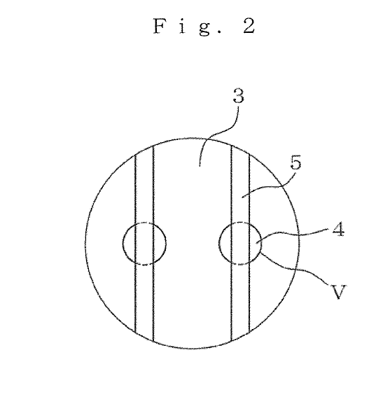

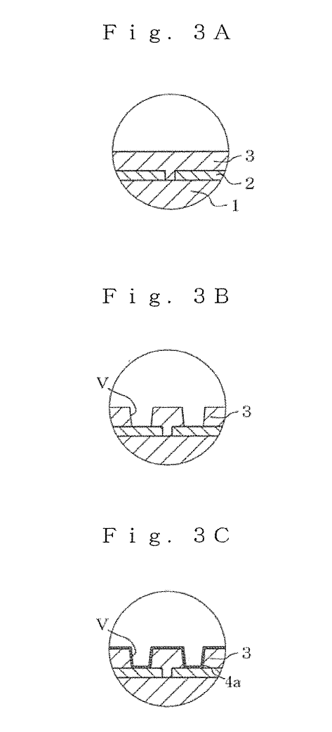

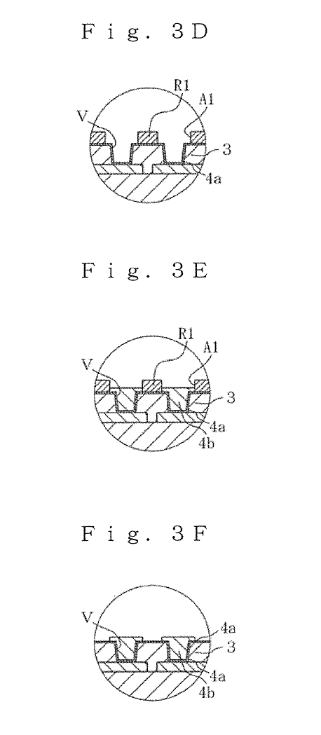

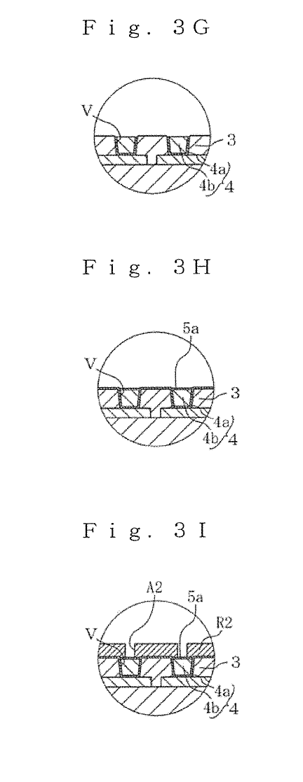

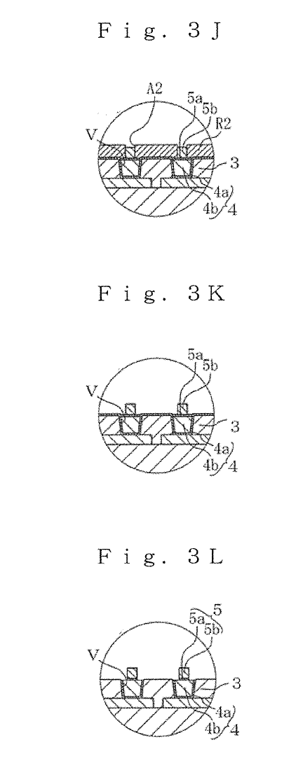

Next, one example of the method for producing the wiring board according to the first embodiment will be described with reference to FIGS. 3A to 3L. As illustrated in FIG. 3A, the upper insulating layer 3 is formed on the lower insulating layer 1 on which the lower wiring conductor 2 has been formed. The upper insulating layer 3 is formed in such a manner that an uncured or partially-cured film or sheet is laminated as the upper insulating layer 3 on the lower insulating layer 1 on which the lower wiring conductor 2 has been formed, and pressed from above and below while being heated. As described above, the lower insulating layer 1 has the thickness of approximately 20 μm to 200 μm, the lower wiring conductor 2 has the thickness of approximately 5 μm to 50 μm, and the upper insulating layer 3 has the thickness of approximately 20 μm to 50 μm.

Subsequently, as illustrated in FIG. 3B, the via-holes V are formed in the upper insulating layer 3. The bottom surface of the via-hole V reaches the lower wiring conductor 2. The via-hole V is formed by laser processing, for example, but the method is not limited to the laser processing. As described above, the upper end portion of the via-hole V has the diameter of approximately 40 μm to 65 μm, and the bottom portion thereof has the diameter of approximately 30 μm to 45 μm. Subsequently, as illustrated in FIG. 3C, the first base metal layer 4a is deposited in the via-hole V and on a surface of the upper insulating layer 3. The first base metal layer 4a is formed by electroless copper plating, for example. The first base metal layer 4a has a thickness of approximately 0.1 μm to 1 μm.

Subsequently, as illustrated in FIG. 3D, a first plating resist layer R1 is formed on the first base metal layer 4a. The first plating resist layer R1 has a first opening pattern A1 to expose the via-hole V and its periphery. An opening diameter of the first opening pattern A1 is larger than an opening diameter of the via-hole V by approximately 10 μm to 20 μm. Subsequently, as illustrated in FIG. 3E, the first electrolytically plated layer 4b is deposited in the first opening pattern A1. The first electrolytically plated layer 4b is deposited so that the via-hole V is completely filled and a thickness on the upper insulating layer 3 reaches approximately 10 μm to 20 μm. The first electrolytically plated layer 4b is formed by electrolytic copper plating, for example. Subsequently, as illustrated in FIG. 3F, the first plating resist layer R1 is peeled and removed.

Subsequently, as illustrated in FIG. 3G, the first base metal layer 4a is removed from the upper insulating layer 3 by etching, and the first electrolytically plated layer 4b is reduced in thickness so that a surface of the first electrolytically plated layer 4b is recessed from the surface of the upper insulating layer 3 by 0 μm to 15 μm. Consequently, the via conductor 4 formed of the first base metal layer 4a and the first electrolytically plated layer 4b formed thereon is formed with its surface recessed from the surface of the upper insulating layer 3 by 0 μm to 15 μm. Subsequently, as illustrated in FIG. 3H, the second base metal layer 5a is deposited on the surface of the upper insulating layer 3 and a surface of the via conductor 4. The second base metal layer 5a is formed by electroless copper plating similar to the first base metal layer 4a, and has a thickness of approximately 0.1 μm to 1 μm.

Subsequently, as illustrated in FIG. 3I, a second plating resist layer R2 is formed on the second base metal layer 5a. The second plating resist layer R2 has an opening pattern A2 passing on the via-hole V and having a width smaller than the via-hole V. The width of the second opening pattern A2 is smaller than the diameter of the via-hole V by 15 μm to 30 μm. In this process, the second plating resist layer R2 is formed on the via conductor 4 which is recessed from the surface of the upper insulating layer 3 by 0 μm to 15 μm, so that the second plating resist layer R2 does not deeply enter the via-hole V. Subsequently, as illustrated in FIG. 3J, the second electrolytically plated layer 5b is deposited on the second base metal layer 5a formed in the second opening pattern A2 of the second plating resist layer R2. The second electrolytically plated layer 5b is deposited so that its thickness from the upper insulating layer 3 reaches approximately 10 μm to 20 μm. The second electrolytically plated layer 5b is formed by electrolytic copper plating layer, for example.

Subsequently, as illustrated in FIG. 3K, the second plating resist layer R2 is peeled and removed. In this process, since the second plating resist layer R2 does not deeply enter the via-hole V, the second plating resist layer R2 can be favorably peeled and removed without leaving its residue in the via-hole V. Finally, as illustrated in FIG. 3L, the second base metal layer 5a which is exposed from the second electrolytically plated layer 5b is removed by etching, and the wiring pattern 5 formed of the second base metal layer 5a and the second electrolytically plated layer 5b is formed on the via conductor 4 and on the upper insulating layer 3. The method for forming the wiring pattern 5 is called a semi-additive method. The etching may be only performed to the extent that the second base metal layer 5a whose thickness is as small as approximately 0.1 μm to 1 μm is removed, so that large side-etching does not occur in the wiring conductor 5. Therefore, the fine wiring conductor 5 having the width smaller than the via conductor 4 can be formed.

In addition, since the wiring conductor 5 is formed on the via conductor 4 which is recessed from the surface of the upper insulating layer 3 by 0 μm to 15 μm, the wiring conductor 5 is not largely recessed on the via-hole V, so that the roughly flat wiring conductor 5 can be formed.

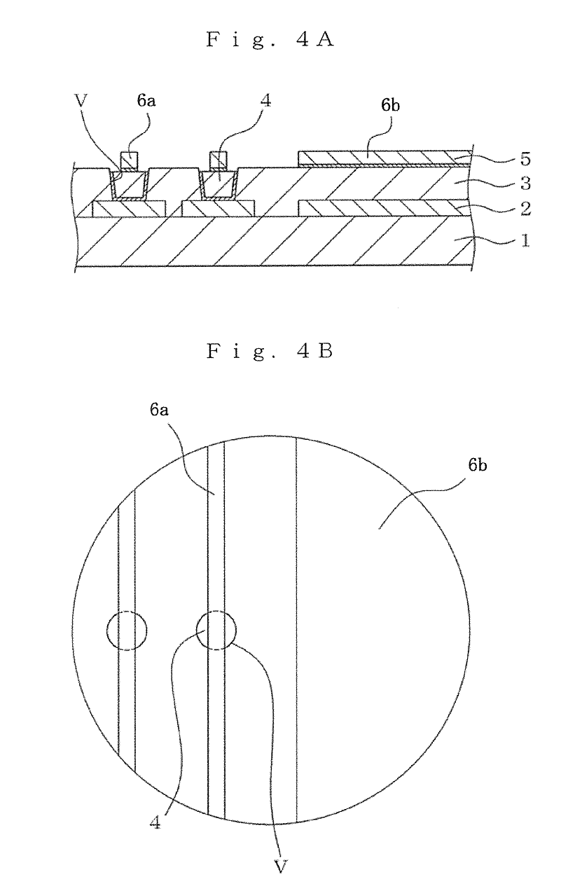

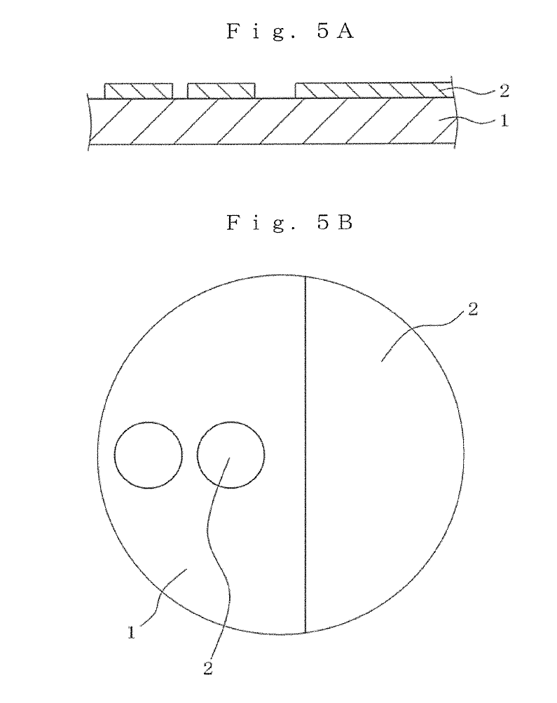

Next, FIGS. 4A and 4B illustrate one example of a wiring board produced by a method for producing a wiring board according to a second embodiment. As illustrated in FIGS. 4A and 4B, in this wiring board, a lower wiring conductor 2 is deposited on a lower insulating layer 1. An upper insulating layer 3 is laminated on the lower insulating layer 1 and the lower wiring conductor 2. Via-holes V are formed in the upper insulating layer 3. A bottom surface of the via-hole V reaches the lower wiring conductor 2. The via-hole V is filled with a via conductor 4. The via conductor 4 is connected to the lower wiring conductor 2. An upper wiring conductor 5 is deposited on the upper insulating layer 3 and on the via conductor 4. The upper wiring conductor 5 has a strip-shaped pattern 6a provided on the via conductor 4 and a solid pattern 6b having a large area.

The lower insulating layer 1, the lower wiring conductor 2, and the upper insulating layer 3 are similar to those in the first embodiment, so that their descriptions are omitted. Each of the via conductor 4 and the upper wiring conductor 5 is a plated conductor layer formed by electroless copper plating or electrolytic copper plating.

The strip-shaped pattern 6a has a width smaller than an upper end of the via conductor 4 and passes on the via conductor 4. Since the width of the strip-shaped pattern 6a is smaller than the upper end of the via conductor 4, the lower wiring conductor 2 and the upper strip-shaped pattern 6a are surely connected through the via conductor 4 even when misalignment is generated between a formation position of the via conductor 4 and a formation position of the upper wiring conductor 5 due to a producing variation. An upper end portion of the via-hole V has a diameter of approximately 40 μm to 65 μm, and a bottom portion thereof has a diameter of approximately 30 μm to 45 μm. The strip-shaped pattern 6a has a width of approximately 30 μm to 45 μm.

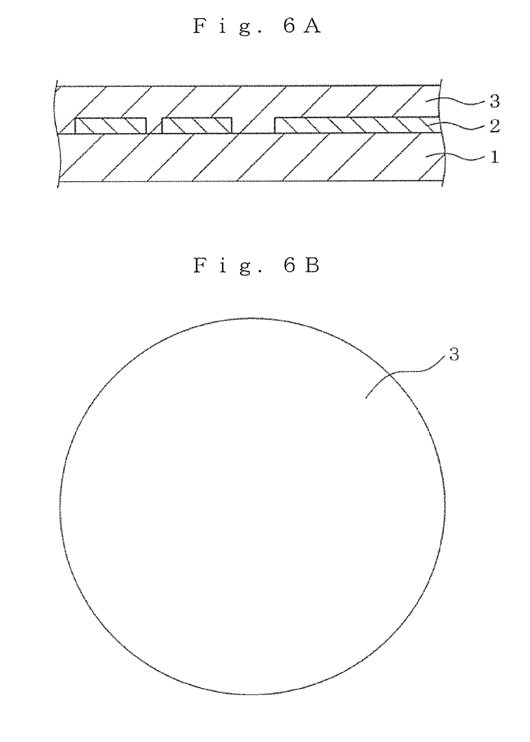

Next, one example of the method for producing the wiring board according to the second embodiment will be described with reference to FIGS. 5A to 16B. As illustrated in FIGS. 5A and 5B, the lower wiring conductor 2 is formed on an upper surface of the lower insulating layer 1. The lower insulating layer 1 is formed of a thermosetting resin containing glass cloth, or formed of a thermosetting resin not containing glass cloth. As described above, the lower insulating layer 1 has the thickness of approximately 20 μm to 200 μm. The lower wiring conductor 2 is a conductor layer covered with metal foil such as copper foil or plated with copper. As described above, the lower wiring conductor 2 has the thickness of approximately 5 μm to 50 μm. The lower wiring conductor 2 is formed by the known subtractive method or a semi-additive method.

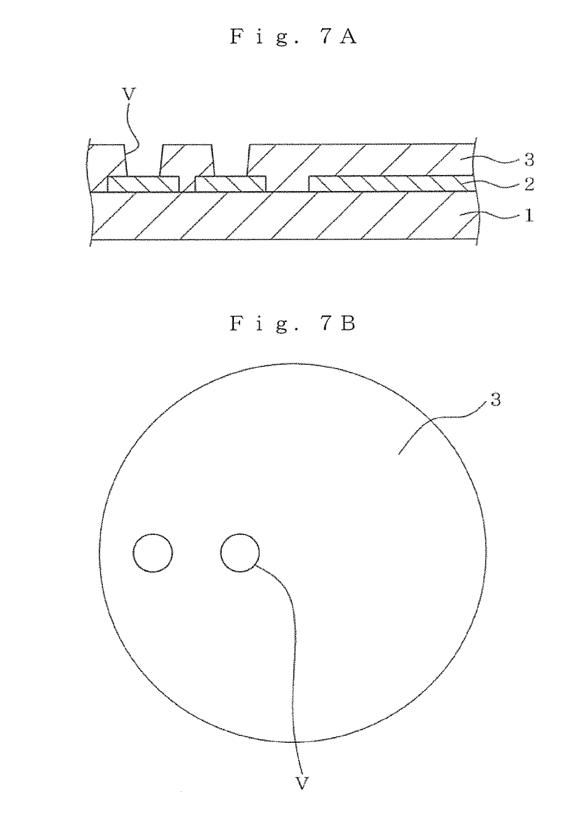

Subsequently, as illustrated in FIGS. 6A and 6B, the upper insulating layer 3 is formed on the lower insulating layer 1 on which the lower wiring conductor 2 has been formed. The upper insulating layer 3 is formed of a thermosetting resin not containing glass cloth, or formed of a thermosetting resin containing glass cloth. As described above, the upper insulating layer 3 has the thickness of approximately 20 μm to 50 μm. The upper insulating layer 3 is formed in such a manner that an uncured or partially-cured film or sheet is laminated as the upper insulating layer 3 on the lower insulating layer 1 on which the lower wiring conductor 2 has been formed, and pressed from above and below while being heated.

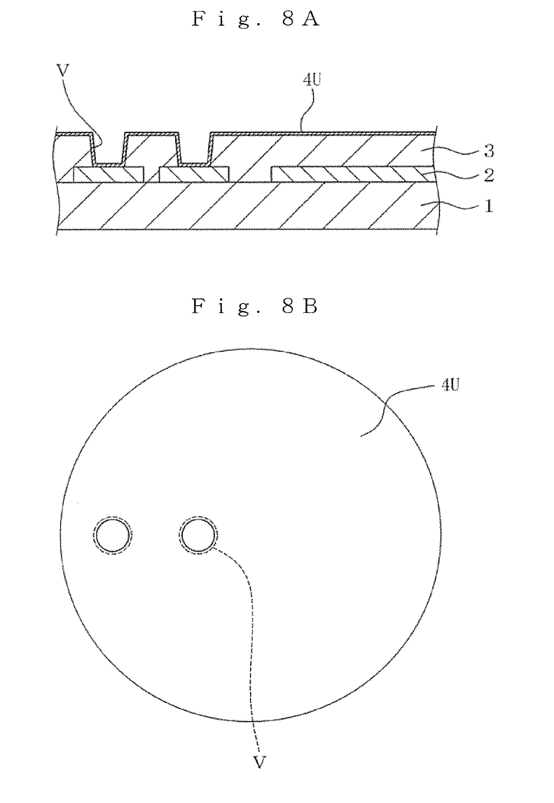

Subsequently, as illustrated in FIGS. 7A and 7B, the via-holes V are formed in the upper insulating layer 3. The bottom surface of the via-hole V reaches the lower wiring conductor 2. The via-hole V is formed by laser processing, for example, but the method is not limited to the laser processing. The upper end portion of the via-hole V has the diameter of approximately 40 μm to 65 μm, and the bottom portion thereof has the diameter of approximately 30 μm to 45 μm. Subsequently, as illustrated in FIGS. 8A and 8B, a first base conductor layer (base metal layer) 4U is deposited for the electrolytic plating, on the upper insulating layer 3 and in the via-holes V. The first base conductor layer 4U is formed by electroless copper plating, for example. The first base conductor layer 4U has a thickness of approximately 0.1 μm to 1 μm.

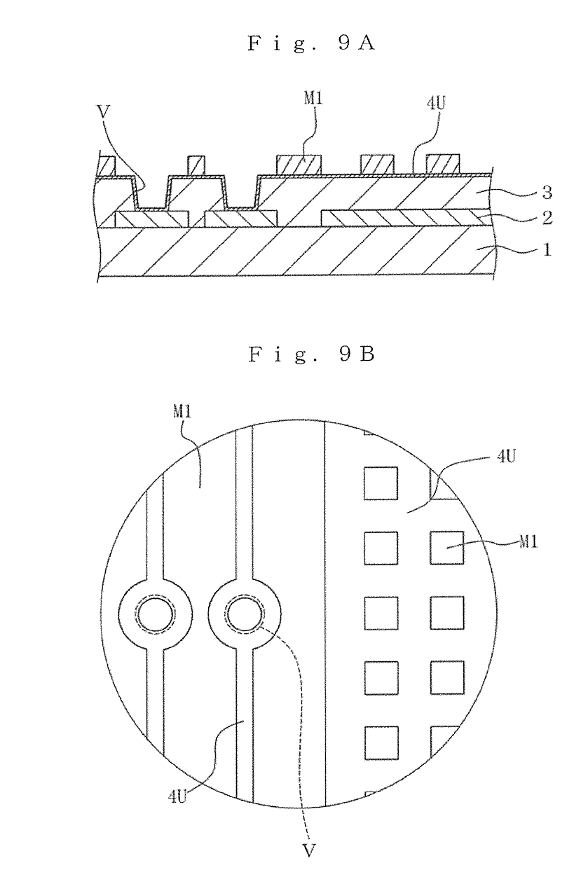

Subsequently, as illustrated in FIGS. 9A and 9B, a first plating mask layer M1 (corresponding to the first plating resist layer R1 in the first embodiment) is formed on the first base conductor layer 4U. The first plating mask layer M1 is formed so as to expose the first base conductor layer 4U provided in the via-hole V and its periphery. The first base conductor layer 4U in the periphery of the via-hole is exposed in a circular shape. A diameter of this portion exposed in the circular shape is larger than the diameter of the via-hole by approximately 20 μm to 50 μm. In addition, the first plating mask layer M1 is formed so as to expose the first base conductor layer 4U having a strip shape corresponding to the strip-shaped pattern 6a, in a portion where the strip-shaped pattern 6a in the upper wiring conductor 5 is to be formed. Furthermore, the first plating mask layer M1 is formed so as to expose the first base conductor layer 4U having a mesh pattern in a portion where the solid pattern 6b in the upper wiring conductor 5 is to be formed.

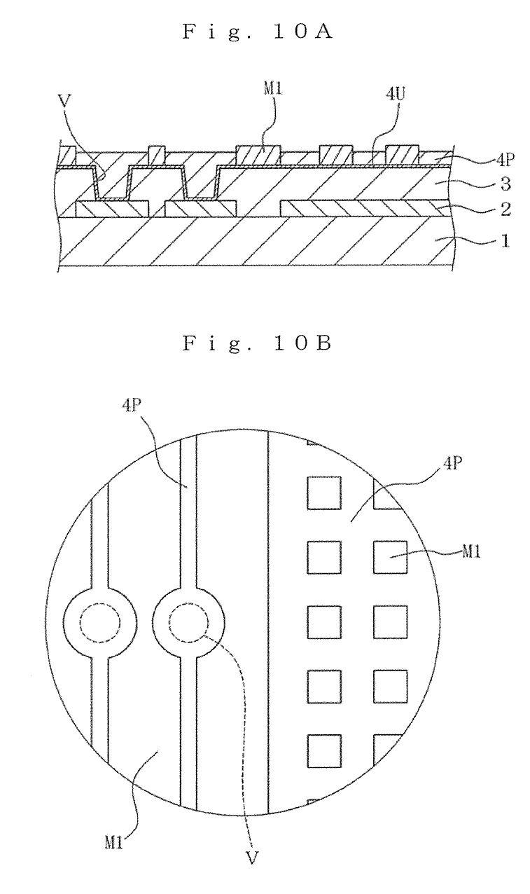

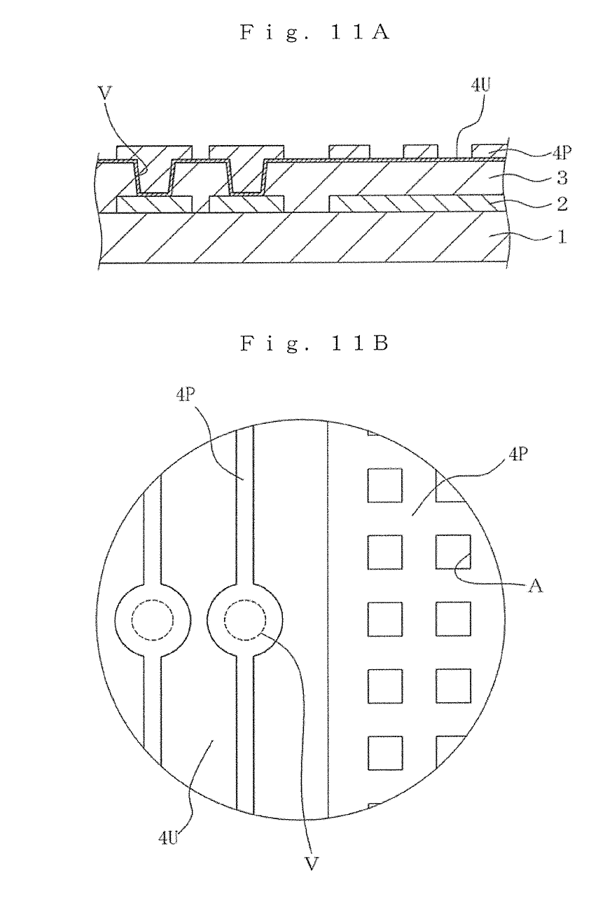

Subsequently, as illustrated in FIGS. 10A and 10B, a first electrolytically plated layer 4P is formed on the first base conductor layer 4U which is exposed from the first plating mask layer M1. The first electrolytically plated layer 4P is formed by electrolytic copper plating, for example. The first electrolytically plated layer 4P has a thickness of approximately 5 μm to 20 μm on the upper insulating layer 3. Subsequently, as illustrated in FIG. 11A and 11B, the first plating mask layer M1 is peeled and removed from the base conductor layer 4U. After this process, the first electrolytically plated layer 4P has a pattern corresponding to a portion where the first plating mask layer M1 has not been formed. That is, the first electrolytically plated layer 4P is deposited on the portion where the upper wiring conductor 5 is to be formed. The first electrolytically plated layer 4P completely fills the via-holes V and covers the periphery of the via-hole V. The covered periphery of the via-hole V has a circular shape larger than the via-hole V by approximately 20 μm to 50 μm. In addition, the first electrolytically plated layer 4P has a strip-shaped pattern similar to the strip-shaped pattern 6a, in the portion to be overlapped with the strip-shaped pattern 6a in the upper wiring conductor 5. Furthermore, the first electrolytically plated layer 4P has a meshed pattern having many openings A, in the portion to be overlapped with the solid pattern 6b in the upper wiring conductor 5.

According to the second embodiment, the first electrolytically plated layer 4P occupies 40% to 55% area of the upper surface of the upper insulating layer 3. This area occupancy can be obtained by adjusting the size, the number, and the position of the openings A. When the first electrolytically plated layer 4P has the above area occupancy, the first electrolytically plated layer 4P can be formed in the via-hole V and on the upper insulating layer 3 with a small thickness variation.

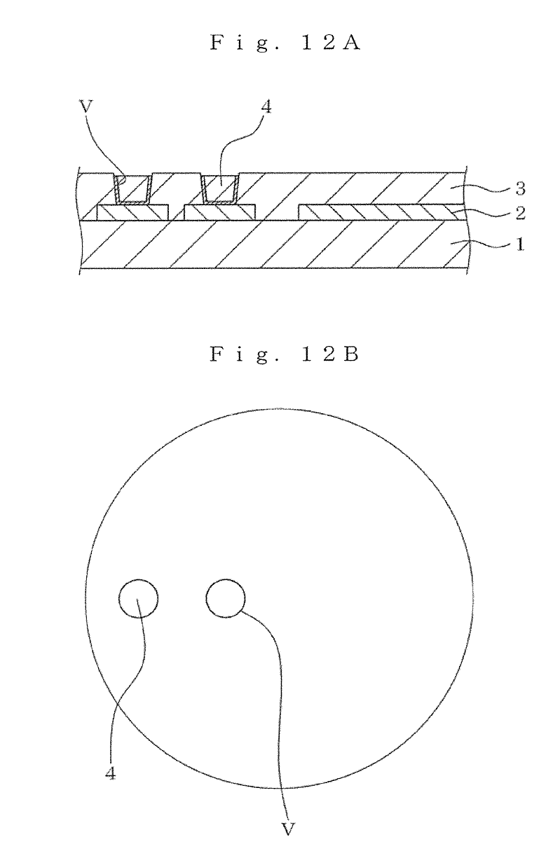

Subsequently, as illustrated in FIGS. 12A and 12B, the via conductor 4 is formed by etching a whole surface of the first electrolytically plated layer 4P to remove the first base conductor layer 4U and the first electrolytically plated layer 4P on the upper insulating layer 3. In this process, the etching is performed until an upper surface of the first electrolytically plated layer 4P in the via-hole V is recessed from an upper surface of the upper insulating layer 3 by 0 μm to 15 μm. Thus, the via conductor 4 formed of the first base conductor layer 4U and the first electrolytically plated layer 4P is formed in the via-hole V with its upper surface recessed from the upper surface of the upper insulating layer 3 by 0 μm to 15 μm. In addition, by setting the area occupancy of the first electrolytically plated layer 4P in the upper surface of the upper insulating layer 3 at 40% to 55%, an etching variation can be small. Therefore, a residue of the first electrolytically plated layer 4P is hardly left on the upper insulating layer 3.

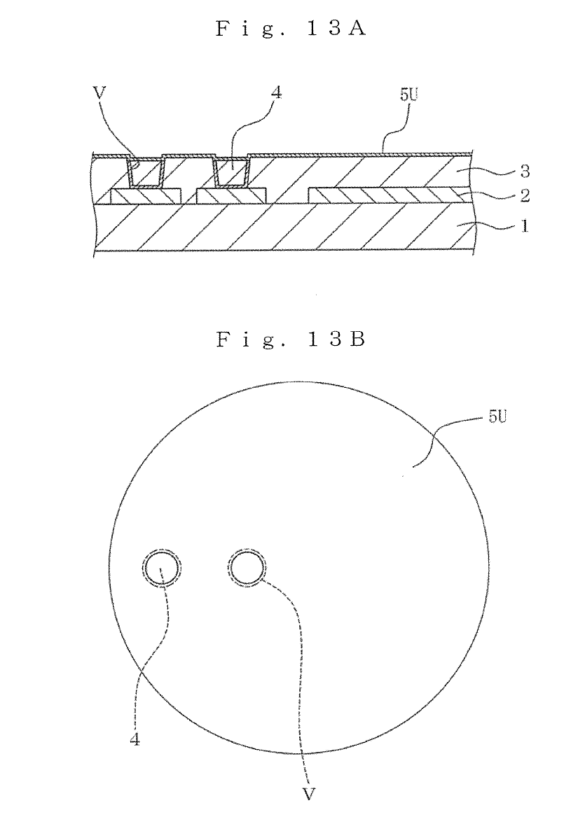

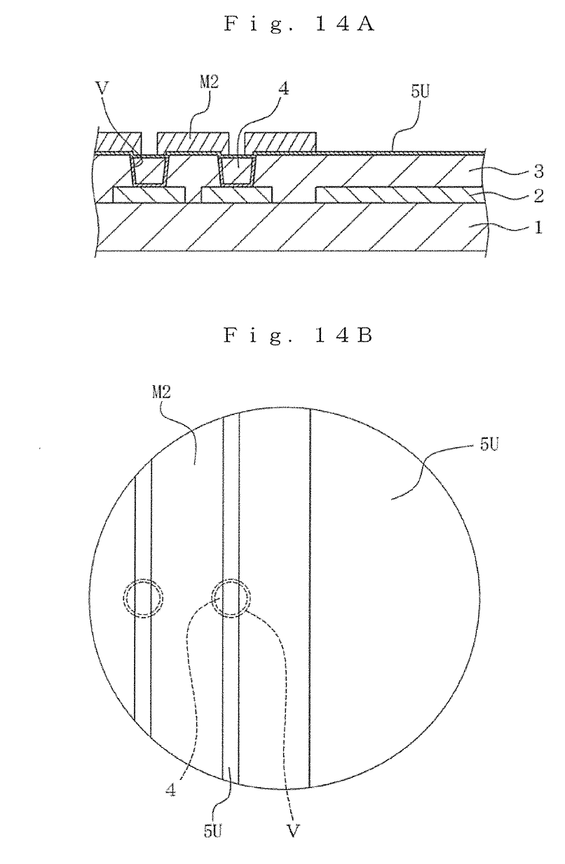

Subsequently, as illustrated in FIGS. 13A and 13B, a second base conductor layer (base metal layer) 5U is deposited on the upper surface of the upper insulating layer 3 and the upper surface of the via conductor 4. The second base conductor layer 5U is formed similarly to the first base conductor layer 4U. Subsequently, as illustrated in FIGS. 14A and 14B, a second plating mask M2 (corresponding to the second plating resist layer R2 in the first embodiment) is formed on the second base conductor layer 5U. The second plating mask M2 is formed so as to expose the second base conductor layer 5U into a pattern corresponding to positions of the upper wiring conductor 5 to be formed on the upper insulating layer 3. That is, the strip-shaped second base conductor layer 5U is exposed so as to correspond to the strip-shaped pattern 6a, in the portion where the strip-shaped pattern 6a in the upper wiring conductor 5 is to be formed. In addition, the second plating mask M2 is formed so as to wholly expose the second base conductor layer 5U in the portion where the solid pattern 6b in the upper wiring conductor 5 is to be formed. In addition, a width of the strip-shaped second base conductor layer 5U on the via conductor 4 is to be smaller than the diameter of the via-hole V by 15 μm to 30 μm. Furthermore, the second plating mask M2 is formed on the via conductor 4 which is recessed from the surface of the upper insulating layer 3 by 0 μm to 15 μm, so that the second plating mask M2 does not deeply enter the via-hole V.

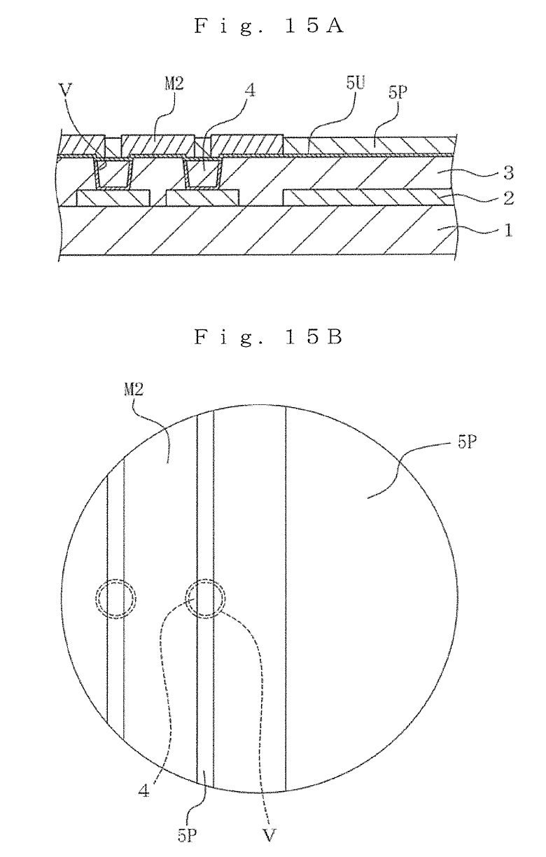

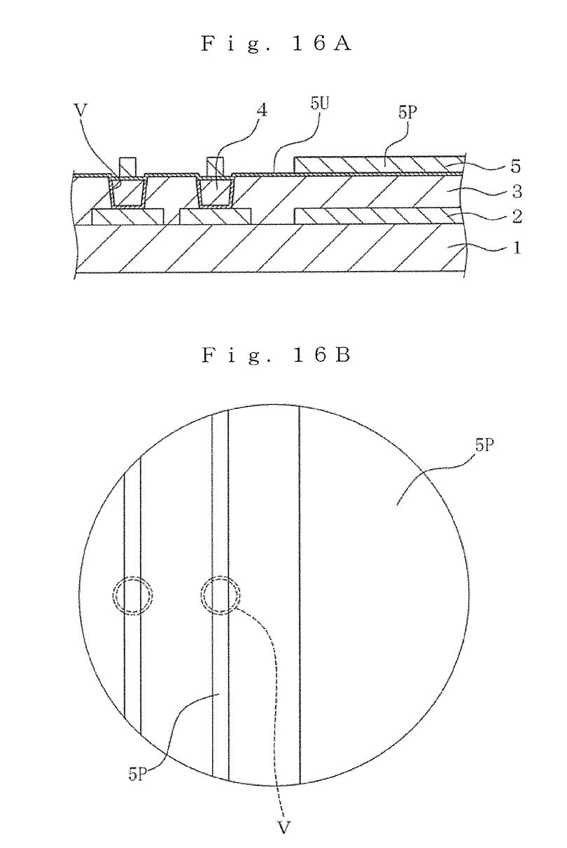

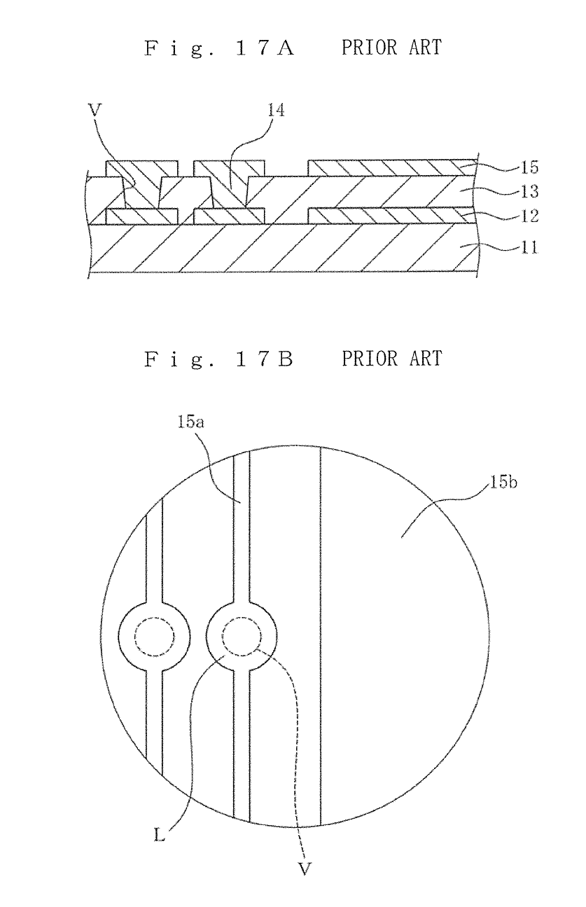

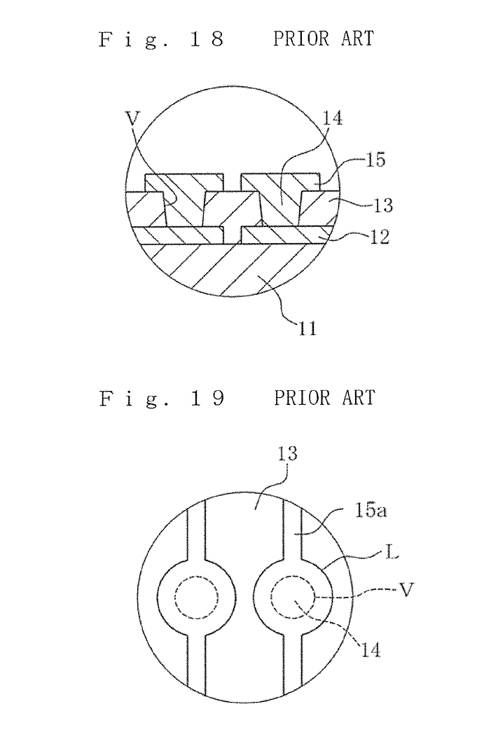

Subsequently, as illustrated in FIGS. 15A and 15B, a second electrolytically plated layer 5P is deposited on the second base conductor layer 5U which is exposed from the second plating mask M2. The second electrolytically plated layer 5P is deposited so that its thickness on the upper insulating layer 3 reaches approximately 10 μm to 20 μm. The second electrolytically plated layer 5P is formed by electrolytic copper plating, for example. Subsequently, as illustrated in FIGS. 16A and 16B, the second plating mask M2 is peeled and removed from the second base conductor layer 5U. In this process, since the second plating mask M2 does not deeply enter the via-hole V, it can be favorably peeled and removed without leaving a residue of the second plating mask M2 in the via-hole V.

Finally, the second base conductor layer 5U which is exposed from the second electrolytically plated layer 5P is removed by etching, and the upper wiring conductor 5 formed of the second base conductor layer 5U and the second electrolytically plated layer 5P is formed on the via conductor 4 and on the upper insulating layer 3. Thus, the wiring board illustrated in FIGS. 4A and 4B is provided by the method for producing the wiring board according to the second embodiment. In this case also, the upper wiring conductor 5 is formed by the semi-additive method. Therefore, as described above, the large side-etching does not occur in the upper wiring conductor 5, so that the fine strip-shaped pattern 6a having the width smaller than the via conductor 4 can be formed with high density.

Thus, according to the method for producing the wiring board in the second embodiment, the via-hole V formed in the upper insulating layer 3 is filled with the via conductor 4 whose upper end is recessed from the upper surface of the upper insulating layer 3 by 0 μm to 15 μm. After that, the upper wiring conductor 5 having the strip-shaped pattern 6a having the width smaller than the upper end of the via conductor 4 is formed on the via conductor 4 by the semi-additive method. Therefore, the fine wiring can be formed on the upper insulating layer 3 with high density. Furthermore, since the strip-shaped pattern 6a is formed on the via conductor 4 which is recessed from the surface of the upper insulating layer 3 by 0 μm to 15 μm, the strip-shaped pattern 6a is not largely recessed on the via-hole V, so that the roughly flat strip-shaped pattern 6a can be formed.

Furthermore, even when the residue of the first electrolytically plated layer 4P is left on the upper insulating layer 3 after the first base conductor layer 4U and the first electrolytically plated layer 4P on the upper insulating layer 3 are etched away, the first electrolytically plated layer 4P is formed in the portion where the upper wiring conductor 5 is to be formed. Therefore, since the upper wiring conductor 5 is formed so as to overlap the residue, the residue does not damage electrical insulating reliability of the upper wiring conductor 5.

The present invention is not limited to the above embodiments, and can be modified variously without departing from the scope of the present invention. For example, according to the first and second embodiments, the horizontal cross-sectional shape of the via-hole V has the circular shape, but it may be a polygonal shape such as a triangular shape or quadrangular shape, or an ellipsoidal shape.

What is claimed is:

1. A method for producing a wiring board comprising the steps of:
forming an upper insulating layer on a lower insulating layer in such a manner as to cover a lower wiring conductor formed on an upper surface of the lower insulating layer;
forming a via-hole in the upper insulating layer in such a manner that its bottom surface reaches the lower wiring conductor;
depositing a first base metal layer in the via-hole and on an upper surface of the upper insulating layer;
forming a first plating resist layer on the first base metal layer having a first opening pattern to expose the via-hole and a periphery of the via-hole;
depositing a first electrolytically plated layer in the first opening pattern to completely fill at least the via-hole;
forming a via conductor including the first base metal layer and the first electrolytically plated layer by removing the first plating resist layer, and recessing a surface of the first electrolytically plated layer from the surface of the upper insulating layer by 0 μm to 15 μm;
depositing a second base metal layer on a surface of the via conductor and an exposed surface of the upper insulating layer;
forming a second plating resist layer on the second base metal layer having a second opening pattern passing on the via-hole and having a width smaller than the via-hole;
depositing a second electrolytically plated layer in the second opening pattern; and
forming an upper wiring conductor including the second base metal layer and the second electrolytically plated layer by removing the second plating resist layer, and etching away the second base metal layer exposed from the second electrolytically plated layer.

2. The method for producing a wiring board according to claim 1, wherein
an upper end portion of the via-hole has a diameter of 40 μm to 65 μm.

3. The method for producing a wiring board according to claim 1, wherein
the upper wiring conductor has a width of 30 μm to 45 μm.

4. The method for producing a wiring board according to claim 1, wherein
the second base metal layer has a thickness of 0.1 μm to 1 μm.

5. A method for producing a wiring board comprising:
a lower insulating layer having a lower wiring conductor thereon;
an upper insulating layer formed on the lower wiring conductor and the lower insulating layer;
a via-hole formed in the upper insulating layer in such a manner that its bottom surface reaches the lower wiring conductor;
a via conductor filled in the via-hole in such a manner that its upper end is recessed from a surface of the upper insulating layer by 0 μm to 15 μm; and
an upper wiring conductor formed on the upper insulating layer and on the via conductor, and having a strip-shaped pattern passing on the via conductor and wherein the strip-shaped pattern has a width smaller than the upper end of the via conductor, the method comprising the steps (1) to (7) of:
(1) forming the lower wiring conductor on the lower insulating layer;
(2) forming the upper insulating layer on the lower insulating layer and on the lower wiring conductor;
(3) forming the via-hole in the upper insulating layer;
(4) depositing a base conductor layer for electrolytic plating, on the upper insulating layer and in the via-hole;
(5) forming an electrolytically plated layer on the base conductor layer on the upper insulating layer, in the via-hole, and on a periphery of the via-hole, in a portion where the upper wiring conductor is to be formed in such a manner that the via-hole is completely filled and an area occupancy of the electrolytically plated layer in the upper surface of the upper insulating layer reaches 40% to 55%;
(6) forming the via conductor by etching a whole surface of the base conductor layer and the electrolytically plated layer in such a manner that the upper surface of the electrolytically plated layer in the via-hole is recessed from the upper surface of the upper insulating layer by 0 μm to 15 μm; and
(7) forming the upper wiring conductor on the upper insulating layer and on the via conductor by a semi-additive method.

6. The method for producing a wiring board according to claim 5, wherein
an upper end portion of the via-hole has a diameter of 40 μm to 65 μm.

7. The method for producing a wiring board according to claim 5, wherein
the strip-shaped pattern has a width of 30 μm to 45 μm.

8. The method for producing a wiring board according to claim 5, wherein
the upper wiring conductor is formed of a second base conductor layer and a second electrolytically plated layer, and
the second base conductor layer has a thickness of 0.1 μm to 1 μm.
